(19) United States
(12) Patent Application Publication
(10) Pub. No.: US 2025/0079364 A1
(43) Pub. Date: Mar. 6, 2025

(54) METHODS AND STRUCTURES EMPLOYING METAL OXIDE FOR DIRECT METAL BONDING

(71) Applicant: ADEIA SEMICONDUCTOR BONDING TECHNOLOGIES INC., San Jose, CA (US)

(72) Inventors: Cyprian Emeka Uzoh, San Jose, CA (US); Oliver Zhao, Sunnyvale, CA (US); Gabriel Z. Guevara, Gilroy, CA (US); Dominik Suwito, San Jose, CA (US); Gaius Gillman Fountain, Jr., Youngsville, NC (US); Rajesh Katkar, Milpitas, CA (US); Thomas Workman, San Jose, CA (US)

(21) Appl. No.: 18/497,810

(22) Filed: Oct. 30, 2023

Related U.S. Application Data
(60) Provisional application No. 63/580,828, filed on Sep. 6, 2023.

(51) Int. Cl. H01L 23/00; H01L 25/00; H01L 25/065

(52) U.S. Cl. CPC H01L 24/08; H01L 24/05; H01L 24/29; H01L 24/32; H01L 24/80; H01L 24/83; H01L 24/94; H01L 25/0655; H01L 25/0657; H01L 25/50; H01L 2224/05647; H01L 2224/05655; H01L 2224/08145; H01L 2224/08225; H01L 2224/29147; H01L 2224/29187; H01L 2224/32145; H01L 2224/80011; H01L 2224/80447; H01L 2224/80455; H01L 2224/80895; H01L 2224/80896; H01L 2224/83011; H01L 2224/94; H01L 2924/152

(57) ABSTRACT

A semiconductor element is provided with a micro-structured metal oxide layer over a conductive feature at a hybrid bonding surface. The micro-structured metal oxide layer comprises fine metal oxide grains, such as nanograins. The grains can be formed over the conductive feature by oxidizing a metal comprised in the conductive feature, or by providing a metal oxide over the conductive feature. When directly bonded to another element, the micro-structured metal oxide layer can form strong bonds at the bonding interface at substantially reduced annealing temperature.

### BACKGROUND

### Field

The field relates to direct bonding of microelectronics, and more particularly to direct metal bonding, such as in hybrid bonding.

### Description of the Related Art

The microelectronics industry has experienced tremendous growth over the past decades. However, the thirst of the market for ever higher input/output (I/O) density and faster connection between chips has been unquenchable. This demand has driven integrated circuit (IC) system designs into 3D architectures. Solder bumps and micro-bumps can provide vertical interconnects between chips by using small metal bumps on dies as one form of wafer-level packaging. Hybrid bonding can provide a solution for superior density of interconnect features.

Hybrid bonding, such as the DBI® technology commercially available from Adeia of San Jose, CA, avoids the use of metal bumps, and instead connects dies in packages using direct metal-to-metal, e.g., copper-to-copper, conductive feature connections. In the bonding layer of each bonding element, conductive features, such as metal contact pads, are embedded in a dielectric material. The hybrid bonding surface can be planarized by chemical mechanical polishing (CMP) and cleaned to remove particles and contaminants. Plasma activation can create active sites on the dielectric of the hybrid bonding surface of at least one of the two elements to be bonded. The two bonding elements are aligned precisely as they are brought together in a bonding equipment and the active sites on the bonding surfaces bond to each other. The dielectric bonding can be processed at room temperature. An annealing process can aid in bonding aligned conductive features, and can also strengthen bonds between the dielectric materials.

While hybrid bonding has greatly improved the ability to form high density and reliable connections between microelectronics, there remains a need to improve yield, reduce cost and/or reduce thermal budget consumption.

### BRIEF DESCRIPTION OF THE DRAWINGS

Specific implementations will now be described with reference to the following drawings, which are provided by way of example, and not limitation.

FIGS. 1-4 are schematic cross-sectional views illustrating an example process for fabricating a semiconductor element having metal oxide on conductive features for hybrid bonding.

FIGS. 5-7B are schematic cross-sectional views illustrating an example process for hybrid bonding an element having metal oxide on conductive features with another element.

FIG. 8A is an atomic force microscope (AFM) graph showing the topography of an upper surface of an experimental die produced according to the processes of FIGS. 1-4.

FIG. 8B is a transmission electron microscope (TEM) image showing a cross-section of an experimental bonded structure produced according to the processes of FIGS. 1-7B.

FIG. 8C is an energy dispersive spectroscope (EDS) line scan across the bonding interface of the experimental bonded structure that produced the image of FIG. 8B.

FIGS. 9-14 are schematic cross-sectional views illustrating another example process for fabricating a semiconductor element having metal oxide on conductive features for hybrid bonding.

FIGS. 15A-16 are schematic cross-sectional views of bonded structures including the semiconductor element of FIG. 14.

FIGS. 17-18 are schematic cross-sectional views illustrating another example process for fabricating a semiconductor element having metal oxide on conductive features for hybrid bonding.

FIGS. 19-21 are schematic cross-sectional views illustrating an example process of hybrid bonding a wafer having metal oxide on conductive features to another wafer.

FIGS. 22-26 are schematic cross-sectional views illustrating an example process for hybrid bonding a wafer having metal oxide on conductive features with a plurality of dies.

FIGS. 27-28 are schematic cross-sectional views illustrating example hybrid bonded structures having conductive features of different widths.

FIG. 29 is a schematic cross-sectional view of two microelectronic elements configured to be hybrid bonded together.

FIG. 30 is a schematic cross-sectional view of a bonded structure comprising the two microelectronic elements in FIG. 29.

### DETAILED DESCRIPTION

Annealing temperatures and annealing durations for forming direct conductor-to-conductor (e.g., metal-to-metal) bonding is of great importance in the fabrication of directly bonded components. Lower annealing temperatures and/or shorter annealing durations are desirable, for example, for reduced consumption of thermal budget and reduced stress due to CTE mismatch. Various bonding layer structures and methods for producing such bonded semiconductor elements can be implemented to achieve lower annealing temperatures to sufficiently fuse contact pads or other conductive features of the bonded semiconductor elements together. One way in which annealing temperatures can be lowered includes providing a metal oxide on the conductive features, which can achieve bonding with lower annealing temperature and can be beneficial despite incorporating oxygen into the bonded metal contacts.

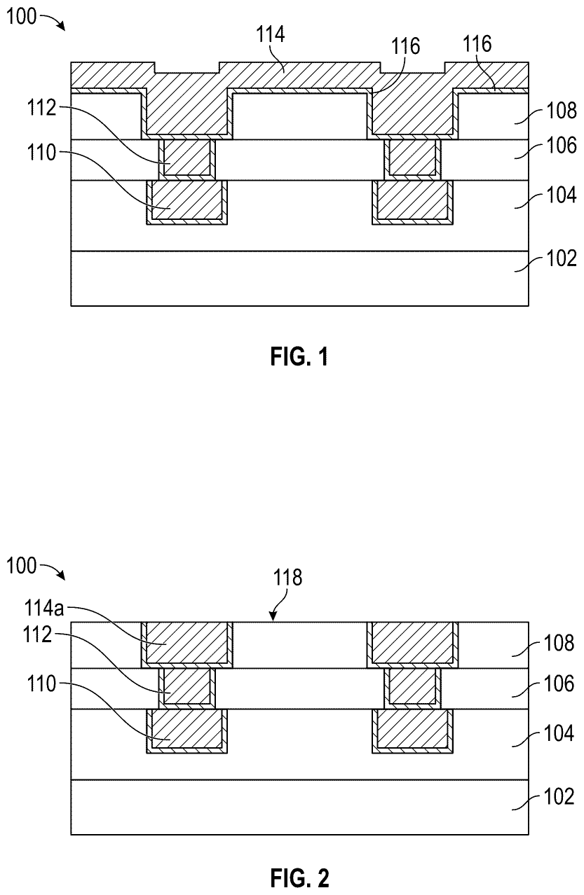

FIGS. 1-4 illustrate an example embodiment of a fabrication process for forming metal oxide on conductive features for direct bonding, such as contact pads, lines or vias. FIG. 1 shows a schematic cross-sectional view of at least a portion of an element 100, such as a microelectronic structure, semiconductor substrate, semiconductor element or microelectronic element. The element 100 can comprise a base substrate 102, such as a bulk semiconductor material (e.g., silicon), an interposer substrate, a semiconductor package substrate, a flat panel substrate, a dielectric substrate, a passive device substrate, or a microelectromechanical systems (MEMS) substrate. The base substrate 102 can comprise active circuitry including transistors and/or other electronic devices formed at least partially therein. A base nonconductive or dielectric material layer 104 can be provided over the base substrate 102 with conductive features 110 embedded therein. A first nonconductive or dielectric layer 106 can be provided over the dielectric material layer 104. Intervening vias 112 can be embedded in the first dielectric layer 106. An upper or second nonconductive or dielectric layer 108 can be provided over the first dielectric layer 106 and a patterned conductive material 114 can be at least partially embedded therein to provide conductive features. In some embodiments, the conductive features can be provided by deposition and etching. In the illustrated embodiment, a stage of damascene processing is shown. Trenches or cavities are formed in the second dielectric layer 108, which are then filled with the conductive material 114. The conductive material 114 may overfill the cavities, including an overburden over field regions of the second dielectric layer 108. A barrier layer 116 may be provided between the second dielectric layer 108 and the conductive material 114 to limit diffusion of the conductive material 114 into the second dielectric layer 108. Additional dielectric layers, such as dielectric barrier materials, can also be provided as part of or between the illustrated dielectric layers 104, 106, 108.

In some embodiments, a seed layer may be disposed on the barrier layer 116, such as by copper sputtering. In some embodiments, the conductive material 114 and the intervening via 112 are formed together, e.g., by a dual damascene process, in which case the barrier layer 116 between the conductive material 114 and the intervening via 112 can be omitted. Other methods are also known in the art for omitting barrier materials between conductive features.

In FIG. 1 each of the first dielectric layer 106 and the second dielectric layer 108 may comprise an inorganic dielectric material, such as silicon oxide, silicon nitride, silicon oxynitride, silicon oxycarbonitride, etc. In some embodiments, one or both of the first dielectric layer 106 and the second dielectric layer 108 can be a low-k dielectric material (e.g., porous silicon oxide, organosilicate glass (SiCOH), or amorphous carbon). Each of the conductive features, including the intervening vias 112, the conductive material 114, and the underlying conductive features 110 can comprise a metal, such as copper, nickel, chromium, gold, indium, ruthenium, tin, platinum, silver, molybdenum, palladium, metal silicide, cobalt, zinc, tungsten, tantalum, titanium, aluminum, and alloys thereof, or a non-metal conductive material (e.g., doped silicon). In some embodiments, the conductive material 114 in the bonding layer predominantly comprises copper.

Referring to FIG. 2, the element 100 may go through an annealing process if desired to optimize grain structure of the conductive features. Subsequently or previously, the excess conductive material 114 and the barrier layer 116 disposed on the top surface of the second dielectric layer 108, and maybe a top portion of the dielectric layer 108, can be removed to leave a planarized upper surface 118, such as by CMP. After planarization, the remaining conductive material portions 114 are confined in their isolated cavities, and thus become conductive features 114a, as shown in FIG. 2. The conductive features 114a can be conductive contact pads or other conductive functional or nonfunctional features, such as dummy pads, lateral traces, or upper ends of vias such as through substrate vias (TSVs). The upper surface 118 of the element 100 includes an upper surface of the second dielectric layer 108 and upper surfaces of the conductive features 114a. For embodiments in which both dielectric and conductive features will be directly bonded, and the planarization is suitable for dielectric direct bonding, the top layer of the element 100, including the second dielectric layer 108 and the conductive features 114a of the illustrated embodiment, can be referred to as a hybrid bonding layer, and the upper surface 118 can be considered a bonding surface. The skilled artisan will appreciate that in other embodiments, the processes described herein can be applied to more complicated or simpler structures than shown in FIG. 2, such as greater or fewer metallization levels between the device level and the bonding layer. The skilled artisan will also appreciate that the processes and structures described herein are also applicable to non-IC microelectronic elements, such as, without limitation, passive devices, MEMS, interposers, and other packaging substrates, etc.

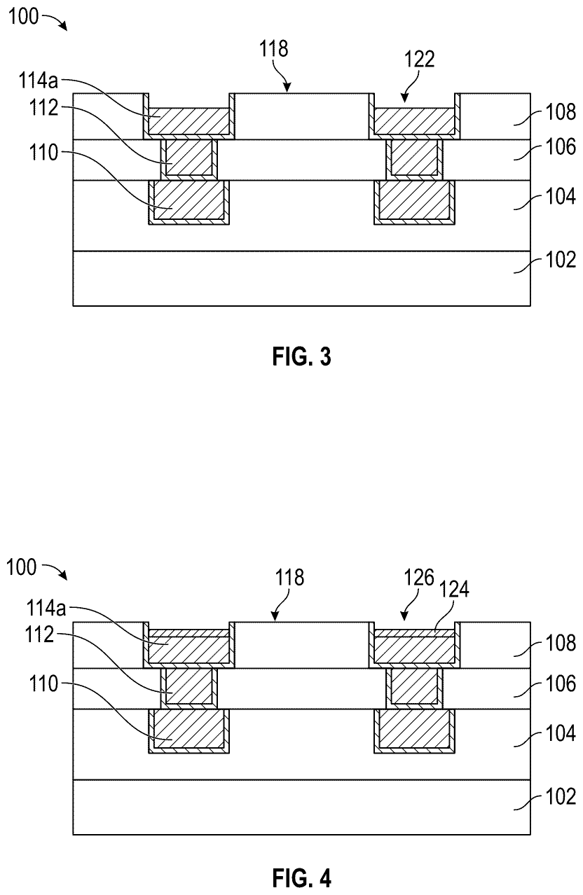

As shown in FIG. 3, top portions of the conductive features 114a are selectively removed (e.g., by etching) to form recesses 122. The depth of the recesses 122 can be between about 5 nm and 30 nm, for example between about 10 nm and 20 mm, or between about 20 nm and 30 nm. In some embodiments, deeper recesses can be formed (e.g., between about 10 nm and 50 nm or even deeper), depending in part upon the structure of the contact features 114a and the expansion volume of the underlying metal during hybrid bonding. The skilled artisan will appreciate that the recesses 122 of FIG. 3 can be formed by a separate recessing operation after planarization and annealing, as discussed above, or can be a result of the CMP process described above with respect to FIG. 2 with proper selection of physical components (e.g., pad hardness, speed) and chemical components (e.g., selectivity of the slurry) to leave the conductive features 114a recessed as schematically illustrated in FIG. 3.

In FIG. 4, the element 100 has been exposed to an oxidation environment that oxidizes upper portions of the conductive features 114a that may comprise a metal. The oxidation process can be a plasma oxidization (e.g., by exposure to an oxygen-containing plasma), thermal oxidization, ozone exposure, or wet oxidation (e.g., by exposure to inorganic or organic oxidants, such as peroxides). In an example, the element 100 of FIG. 3 can be subjected to an ashing process, in which products of oxygen-containing plasma are supplied to the element. Such a process is referred to as “ashing” because it is traditionally employed for burning off organic photoresist. In some embodiments, the oxidation can coincide with removal of photoresist, other organic protective layers, and/or residue left from such organic materials.

As illustrated in FIG. 4, during the oxidation process, oxygen can react with metal exposed at the upper surfaces of the conductive features 114a. As such a metal oxide layer 124 forms selectively over each of the conductive features 114a. Because such an oxidation process relies on diffusion, the metal oxide in the metal oxide layer 124 and the metal in the conductive feature 114a underneath may be intertwined. The average thickness of the metal oxide layer 124 can be at least 2 nm, and in some embodiments can be as thick as 30 nm, such as between about 5 nm and 30 nm, or between about 10 nm and 25 nm. The metal oxide layer 124 tends to have a grainy microstructure, such as nanograins, with a surface roughness of at least about 1 nm Root Mean Square (RMS), or at least about 2 nm RMs, such as between about 2 nm RMS and 5 nm RMS, or between about 1.5 nm RMS and 4 nm RMS. For example, the metal oxide may comprise grains having an average size (e.g., average of a maximum grain dimension) in the range of about 2 nm to 100 nm (e.g., an average size in a range of about 3 nm to 80 nm, or in a range of about 5 nm to 50 nm). The growth of oxide and the tendency to form a microstructure (e.g., nanograins or micro-voids) may cause the resultant metal oxide layer 124 to expand volume. Depending upon the depth of the pre-oxidation recess 122, the expansion may leave a shallower recess 126 as shown, or may cause the metal oxide to protrude above the upper dielectric surface of the hybrid bonding layer. If a recess after the protruding is desired, a selective metal oxide etch may be applied to recess the metal oxide layer 124 to within the cavity in the second dielectric layer 108, forming the illustrated shallow recess 126 above the metal oxide layer 124. The upper surface 118 of FIG. 4 includes both dielectric surfaces (which can be prepared for direct bonding) and the surface of the metal oxide layer 124.

In FIG. 4, during the process of oxidation the conductive feature 114a may be decoupled or unpinned from the surrounding second dielectric layer 108, due to some oxidation along sidewalls of the conductive feature 114a and/or the surrounding barrier layer 116. Such decoupling may facilitate free expansion of the conductive features 114a and the metal oxide layer 124 thereover relative to surrounding materials during the subsequent bonding annealing, thus enhancing the bonding process.

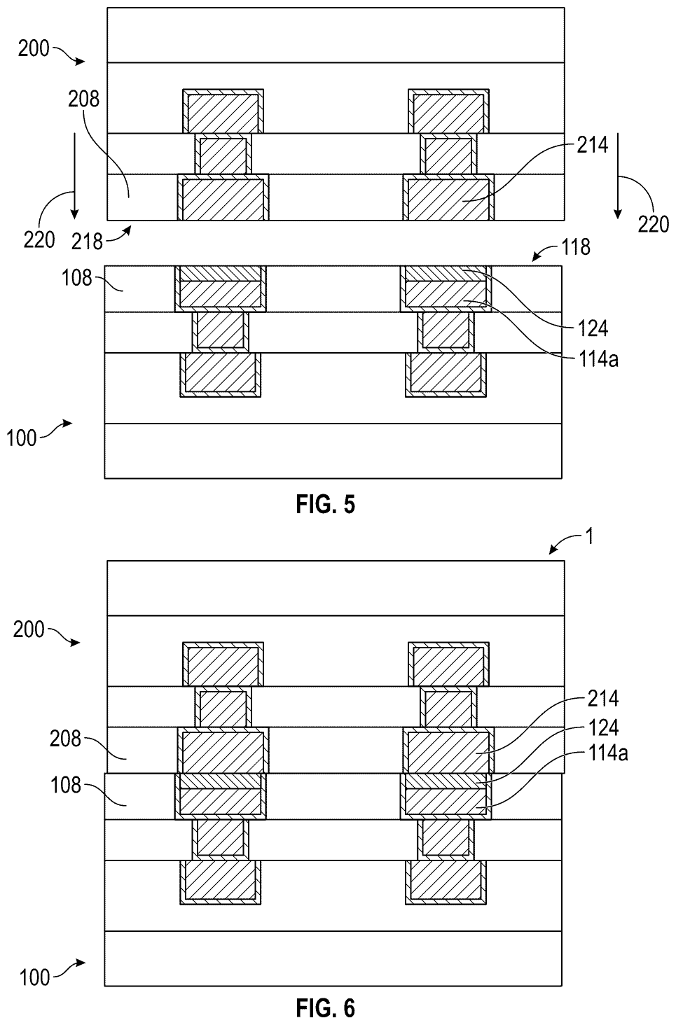

Referring to FIG. 5, the element 100 (first element) of FIG. 4 and a second element 200 are ready to be bonded. One or both of the elements 100, 200 can be prepared for direct bonding as described herein, including planarization suitable for direct bonding and activation and/or termination to increase dielectric-dielectric bond strength. While the first element 100 comprises the metal oxide layer 124, which can have a microstructure as described, on each of the conductive features 114a at the upper surface 118, the second element 200 does not have such metal oxide layers on conductive features 214. In other embodiments, the conductive features 214 of the second element 200 can include metal oxide layers just like the first element 100 does. As shown in FIG. 5, the conductive features 214 of the second element 200 are aligned with the corresponding conductive features 114a of the first element 100. After alignment of the conductive features 114a, 214, the second element 200 is moved along direction 220 (e.g., operated by a bonding equipment) to be directly bonded with the first element 100.

In FIG. 6, the second element 200 is directly bonded to the first element 100 without an intervening adhesive to form a bonded structure 1. As noted, the bonding surface (upper surface 118) of the first element 100 and/or a bonding surface 218 of the second element 200 may be activated and/or terminated prior to the hybrid bonding process. For example, the upper surface 118 of the first element 100, including the metal oxide layer 124, can be exposed to a nitrogen-containing plasma, which can result in elevated nitrogen content near the bonding interface for both insulating and conductive materials. As such a dielectric layer 208 of the second element 200 can be directly bonded to the second dielectric layer 108 of the first element 100. The initial direct bonding of the dielectric surfaces may be performed at room temperature. At this stage, the conductive features 214 of the second element 200 are not (fully) bonded to the conductive features 114a of the element 100. In some embodiments, the conductive features 114a, 214 of both elements 100, 200 are recessed relative to their surrounding dielectric layers 108, 208 such that there is a gap (not shown) between the corresponding conductive features 114a, 214 at the stage of FIG. 6.

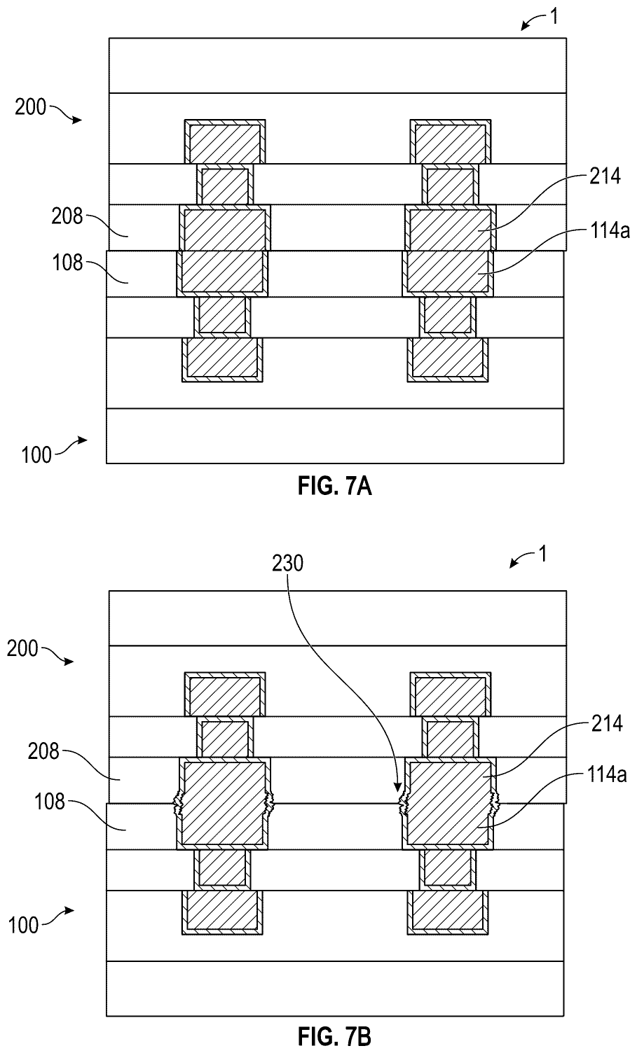

Moving to FIG. 7A, the bonded structure 1 is subjected to an annealing process to heat the bonded elements 100 and 200 to an elevated temperature for a duration sufficient to complete bonding of the conductive features 114a to the conductive features 214. Bonds between the dielectric layers 108, 208 can also be strengthened during the annealing process. During the annealing process, the conductive features 114a of the first element 100 can expand due to the CTE mismatch between the metallic material of the conductive features 114a (and any underlying metal features) and the surrounding second dielectric material 108. Skilled artisans appreciate that in general CTE for dielectric material (e.g., silicon oxide) is smaller than CTE of conductive material (e.g., copper). Also due to the CTE mismatch, the conductive features 214 of the second element 200 can have a tendency to expand, similar to the conductive features 114a. The expansion of the conductive features 114a, 214 causes the metal oxide layer 124 over each of the conductive features 114a to press against the corresponding conductive feature 214. The free movement of the conductive features 114a, including the metal oxide layer 124 disposed there over, due to the sidewall decoupling disclosed above enhances the pressure between the conductive features 114a, 214 from thermal expansion. At the elevated annealing temperature and under the force of the expansion, the conductive features 114a, 214 may be directly bonded to one another.

During the annealing process, the elevated annealing temperature and the extended annealing duration may cause the metal oxide layer 124 to go through changes. First of all, oxygen in the metal oxide layer 124 may be released. Part of the oxygen may diffuse into the connected conductive feature 114a, 214. Secondly, some residual metal oxide of the metal oxide layer 124 may migrate away from the initial interface into the connected conductive features 114a, 214. As such, after annealing the conductive features 114a, 214 may have a relatively high oxygen content in the form of residual metal oxide, free oxygen, and/or dissolved oxygen. The oxygen content may exceed the typical oxygen concentration of less than 20 ppm in electroplated copper. For example, the oxygen content of the merged conductive features 114a, 214, within about 100 nm of the bond interface, may be greater than 50 ppm, such as between 100 ppm and 10,000 ppm or between 60 ppm and 5,000 ppm. In some embodiments, the oxygen content within about 100 nm of the bond interface may exceed the oxygen saturation level(s) of the material of the conductive feature(s) 114a and/or 214, such as greater than 120 ppm saturation level of oxygen in copper. For comparison, copper features below the bonding layer 114a (e.g., redistribution layers or BEOL below contact pads) can have oxygen content of less than 20 ppm. Where the metal oxide layer 124 is exposed to nitrogen (e.g., nitrogen-containing plasma products) for activation and/or termination of the insulating layer, nitrogen content incorporated into the bonded metal features can also increase relative to processes in which no metal oxide is added to the conductive features, and was found to be in the range of about 5% to 200% of that of a nominal pad 114a without the formed metal oxide layer 124.

After annealing, the conductive features 114a of the element 100 may be fused with and bonded to the corresponding conductive features 214 of the element 200 via the metal oxide layer 124. Electrical connections may be formed between the corresponding conductive features 114a and 214 with surprisingly low electrical resistance despite the initial presence of metal oxide at the interface. Further, the physical diffusion may cause the microstructure of the conductive material to change. At the end of the annealing process, metal grains from the conductive features 114a, 214 may have grown to extend across the hybrid bonding interface.

Referring to FIG. 7B, due to the CTE mismatch between the conductive features and the surrounding dielectric materials, the conductive features 114a and the corresponding conductive features 214 are pressed against each other. The metal oxide layers 124 over the conductive features 114a shown in FIG. 6 before annealing may be fused with the opposite conductive features 214. In some embodiments, the force developed from the CTE mismatch and the fusion at the elevated annealing temperature may cause the conductive features 114a, 214 in the bonded region 230 at the hybrid bonding interface to swell outward, forming a sidewall structure having bulging sideways, as schematically indicated in FIG. 7B. In some embodiments, there may not be bulging sidewall at the bonding interface. The profile and the microstructure of the bonded region 230 may depend on the annealing temperature and the annealing duration, in addition to the microstructure between the conductive features at the time of hybrid bonding. Similarly, whether any residual microstructural signature (e.g., nanograin structure) from the metal oxide layer 124 remains in the bonded structure 1 to differentiate grain structures at the interface from more remote locations of the conductive features 114a, 214 can also depend upon the annealing temperature and duration.

The metal oxide layer 124 can help achieve lower annealing temperature with good quality direct bonding of conductive features (equivalent or better bonded conductor conductivity and yield), when compared with bonding two semiconductor elements without the metal oxide layer 124. Microstructure provided by the metal oxide layer 124 can reduce bonding temperatures and enhance metal diffusion. Furthermore, any oxidation of sidewalls of the conductive features can also decouple the conductive features from the surrounding dielectric, facilitating conductive feature expansion and thus also lowering anneal temperatures for a given amount of expansion. The physical stress imparted by ready expansion of the conductive features into one another also facilitates metal grain growth across the bond interface at lower temperatures. Both aspects can facilitate the use of reduced or no recesses in the conductive features relative to the surrounding dielectric, which can improve both uniformity across a substrate and reduced annealing temperatures for given metal bond conductivity, reliability and yield. Further benefits may be achieved when both the first element 100 and the second element 200 have metal oxide layers on their conductive features 114a and 214. However, when one of the first element 100 and the second element 200 includes a metal oxide layer on its conductive features 114a or 214, annealing temperature can be substantially reduced relative to anneal temperatures for equivalent metal bond reliability without intervening metal oxide. For example, if the conductive features 114a of the first element 100 and the conductive features 214 of the second element 200 are both made of copper without a metal oxide layer between them, the annealing temperature may be 250° C. or higher to achieve low electrical resistance and high process yield. When one of the first and second elements 100 and 200 has metal oxide layers 124 on its conductive features 114a or 214, the annealing temperature may be below 250° C., below 200° C., or below 180° C. to achieve equivalent electrical resistance and process yield results. For example, the anneal temperature for directly bonding the conductive features 114a to conductive features 214 can be reduced in a range of 150° C. to 250° C., 100° C. to 200° C., or 80° C. to 180° C. The scale of temperature reduction for equivalent annealing effectiveness may also be affected by the microstructure of the metal oxide layer 124. For example, the annealing temperature for metal oxide grains average size of about 10 nanometers may be significantly lower than the annealing temperature for metal oxide grains average size of about 50 nanometers for equivalent bonding effectiveness.

In some embodiments, the conductive features 114a of the first element 100 comprises predominantly (>50 atom %) copper, and the conductive features 214 of the second element 200 can comprise a common metallic material, e.g., copper, silver, nickel, gold, indium, zirconium, molybdenum, zinc, tungsten, tantalum, or titanium, aluminum, or alloys thereof. In some embodiments, the metallic material forming the conductive features 114a and the conductive features 214 may comprise two different metals respectively. For example, the metallic material of the conductive features 114a of the element 100 predominantly comprises copper, and the metallic material of the conductive features 214 of the element 200 comprises nickel, thus a copper to nickel (Cu/Ni) combination. Other combinations of the metallic materials for the conductive features 114a, 214 can include copper to manganese (Cu/Mn) combination, and copper to silver (Cu/Ag).

Experiments were performed to prepare a first element (e.g., die) 100 following the process described with respect to FIGS. 1-4 to form a copper oxide layer over a copper contact pad embedded in a silicon oxide dielectric material. The copper contact pad and the surrounding silicon oxide together form a bonding layer. The first element 100 was then directly bonded to a second element 200 that had a corresponding copper contact pad following the process described with respect to FIGS. 5-8. Specifically, the first element 100 was subjected to an ashing process by exposing to an oxygen-containing plasma for a duration between 60 seconds to 31 minutes. After the formation of the metal oxide layer 124 on the conductive layer 114a of the first element 100, the bonding surface was activated. In some embodiments, both the first and second elements 100, 200 may be activated. The prepared bonding surfaces were cleaned or rinsed with DI water and dried. After bonding, the bonded structure 1 were subjected to an oven annealing at 200° C. for 2 hours to bond the contact pads of the 114a and 214. A chain resistance of the bonded structure (an electrical path through multiple bonded contact pads) for testing purpose was measured on the first element 100 at room temperature. After the electrical measurement, additional thermal treatments may be performed, for example, by a thermal annealing at 225° C. for 1 hour and another anneal at 250° C. for 1 hour. An intermediate electrical test can be performed between the last two annealing processes.

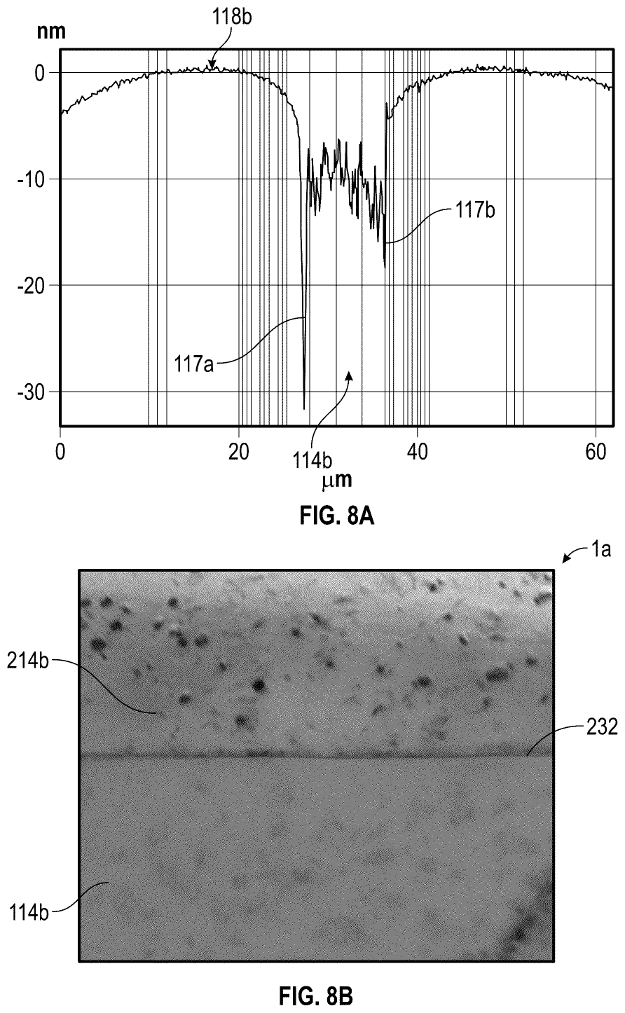

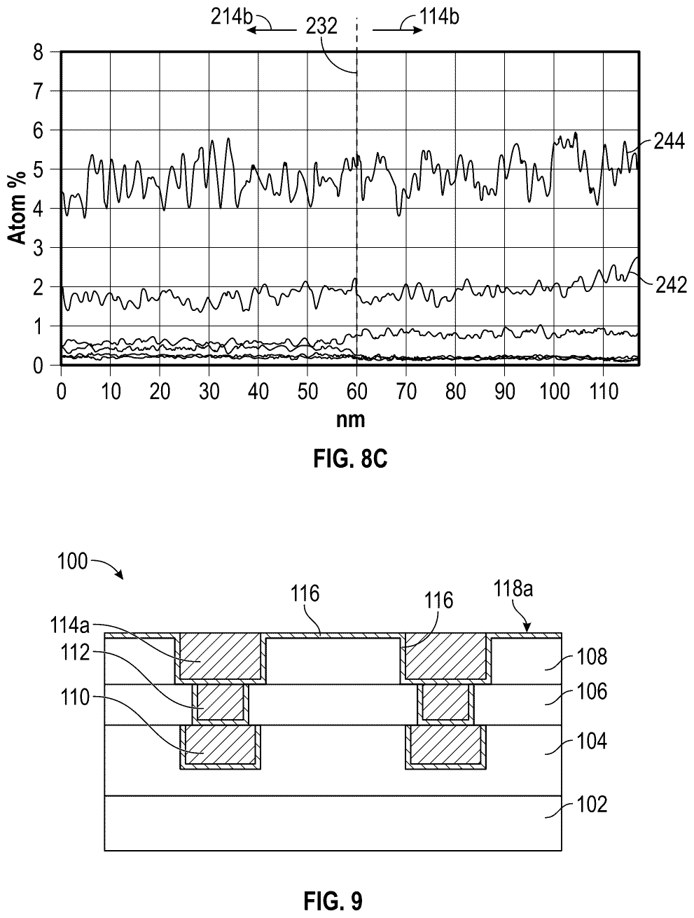

FIG. 8A is an atomic force microscope (AFM) graph to represent the topography of an upper surface 118b of the first die after the ashing process to form a copper oxide layer on top of a copper contact pad 114b. It can be seen that the copper contact pad 114b having copper oxide thercover was recessed by about 10 nm. Further, the sidewalls of the copper contact pad 114b showed indications of decoupling 117a and 117b. The indications of decoupling 117a reached more than 20 nm down from an upper surface of the copper contact pad 114b. The indications of decoupling 117a shown in FIG. 8A resembled a physical gap at the sidewall of the copper contact pad 114b. As discussed above and will be further delineated, such decoupling may facilitate free expansion of the copper contact pad 114b relative to surrounding materials during the subsequent bonding and annealing, thus enhancing the bonding quality.

The experimental results also show that after ashing, the upper surface of the copper contact pad 114b of the first die was roughened. For example, after ashing for 21 minutes, the surface roughness of the copper contact pad 114b increased to about 2.56 nm RMS. After ashing for 31 minutes, the surface roughness of the copper contact pad 114b increased to about 2.89 nm RMS. These results are compared to a control sample that had not been through the ashing process. The surface roughness of the copper contact pad 114b for the control sample was about 1.24 nm RMS. The increased surface roughness of the copper contact pad 114b means that formed copper oxide may have a microstructure of ultra fine grains, or nanograins.

FIG. 8B shows a transmission electron microscope (TEM) image of a cross-section of a portion of a bonded structure 1a produced in the experiment described above. As can be seen, the contact pad 114b of the first die was tightly bonded to a contact pad 214b of the second die, leaving no gap between them at an interface 232. No clear metal layer having fine grains was present at the top portion of the copper contact pad 114b, as described with respect to FIGS. 7A and 7B. The experimental results demonstrate high yield with high bonding strength and low electrical resistance.

FIG. 8C is an energy dispersive spectroscope (EDS) line scan across the interface 230 of the bonded structure 1a. In FIG. 8C, the interface 232 is located in the middle at the 60 nm position. The copper contact pad 114b of the first die is on the right side of the 60 nm position, as indicated in FIG. 8C. The graph of FIG. 8C includes an oxygen content curve 242 and a nitrogen content curve 244. It can be seen that oxygen content curve 242 is in a range of about 1.5 atom % to close to 3 atom %. This level of oxygen content is higher than in the control sample. The higher oxygen content may come from the copper oxide formed during the ashing process. The high level of nitrogen content, which is in a range of about 3.8 atom % to about 6 atom %, may come from a separate activation/termination of the first and second dies, e.g., by exposure to a nitrogen-containing plasma.

In the embodiment shown in FIGS. 1-4, the metal oxide layers 124 are formed by oxidation of the upper surfaces of the conductive features 114a. One advantage of the oxidation process of FIGS. 1-4 is that the metal oxide layers 124 can be formed selectively and directly on the conductive features 114a. However, metal oxide grains can be formed at the upper surface of the conductive features 114a in other ways.

FIGS. 9-18 illustrate example embodiments that provide metal oxide layers over conductive features 114a by different techniques.

The process starts from the structure shown in FIG. 1, where an element 100 is formed having the patterned conductive material 114 at least partially embedded in the second dielectric layer 108. The conductive material 114 may be connected through intervening vias 112 to underlying conductive features or circuitry buried in the layer 104. At the illustrated stage of processing, the conductive material 114 still includes overburden on field regions of the second dielectric layer 108. A barrier layer 116 may be provided between the second dielectric layer 108 and the conductive material 114, including the horizontal separation between the second dielectric layer 108 and the conductive material 114, to limit diffusion of the conductive material 114 into the second dielectric layer 108.

Similar to the process illustrated in FIG. 2, the element 100 may go through an annealing process if desired to optimize grain structure of the conductive features. Subsequently, the excess conductive material 114 disposed on the barrier layer 116 can be removed to leave a planarized upper surface 118a, such as by CMP. After planarization, the remaining conductive material portions 114 are confined in their isolated cavities, and thus become conductive features 114a, as shown in FIG. 9. Unlike FIG. 2, the upper surface 118a of the element 100 comprises surface of the barrier layer 116 and upper surfaces of the conductive features 114a to facilitate a subsequent polishing process. The conductive features 114a can be conductive contact pads or other conductive functional or nonfunctional features, such as dummy pads, lateral traces, or the upper ends of vias, e.g., through substrate vias (TSVs). For embodiments employing hybrid bonding, the top layer of the element 100, including the second dielectric layer 108 and the conductive features 114a of the illustrated embodiment, can be referred to as a hybrid bonding layer, although the upper surface 118a may not yet be prepared for hybrid bonding in the example of FIG. 9. The skilled artisan will appreciate that in other embodiments, the processes described herein can be applied to more complicated or simpler structures than shown in FIG. 9, such as greater or fewer metallization levels between the device level and the bonding layer. The skilled artisan will also appreciate that the processes and structures described herein are also applicable to non-IC microelectronic elements, such as, without limitation, passive devices, MEMS, interposers, and other packaging substrates, etc.

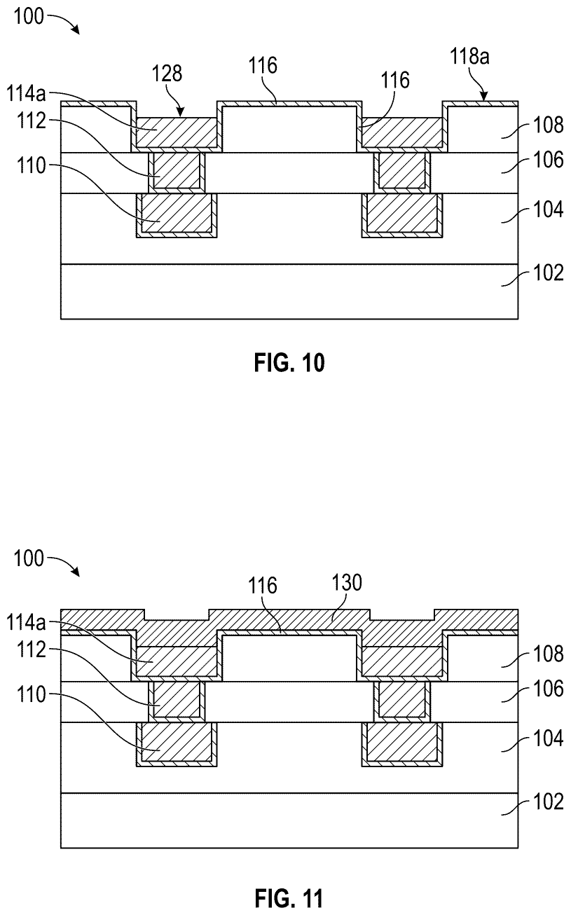

As described with respect to FIG. 3, top portions of the conductive features 114a can be selectively removed (e.g., by etching) to form recesses 128, as shown in FIG. 10. The recess can be formed during polishing of the overburden from the conductive feature 114a or in a subsequent wet or dry etchback. The depth of the recesses 128 can be between about 0.1 μm and 0.5 μm (100 nm and 500 nm), for example between about 100 nm and 300 mm, or between about 200 nm and 400 nm. In some embodiments, shallower or deeper recesses can be formed, e.g., between about 50 nm and 100 nm or between 400 nm and 800 nm, depending in part upon the structure of the contact features 114a and the specific thin film processes involved.

Referring to FIG. 11, the element 100 may be cleaned (e.g., by sputter-cleaning). Subsequently a metal layer 130 is coated over the recesses 128 and the upper surface of the barrier layer 116. The metal layer 130 and the conductive features 114a may both comprise for example, predominantly copper. In some embodiments, the metal layer 130 may comprise copper, and the conductive features 114a may comprise a different material, such as nickel, chromium, gold, indium, ruthenium, tin, platinum, silver, molybdenum, palladium, metal silicide, cobalt, zinc, tungsten, tantalum, titanium, aluminum, and alloys thereof or with copper, or a non-metal conductive material (e.g., doped silicon). The metal layer 130 may be coated by physical vapor deposition (PVD) at a temperature below 100° C. (e.g., below 50° C.). In some embodiments, the metal layer 130 can be formed from a liquid deposition solution (plating) or suspension (spin-on deposition) onto the upper surfaces of the element 100. The metal layer may have a microstructure as formed. For example, metal grains in the metal layer 130 may have an average size (e.g., average of a maximum grain dimension) in the range of about 2 nm to 100 nm (e.g., an average size in a range of about 8 nm to 80 nm, or in a range of about 5 nm to 50 nm).

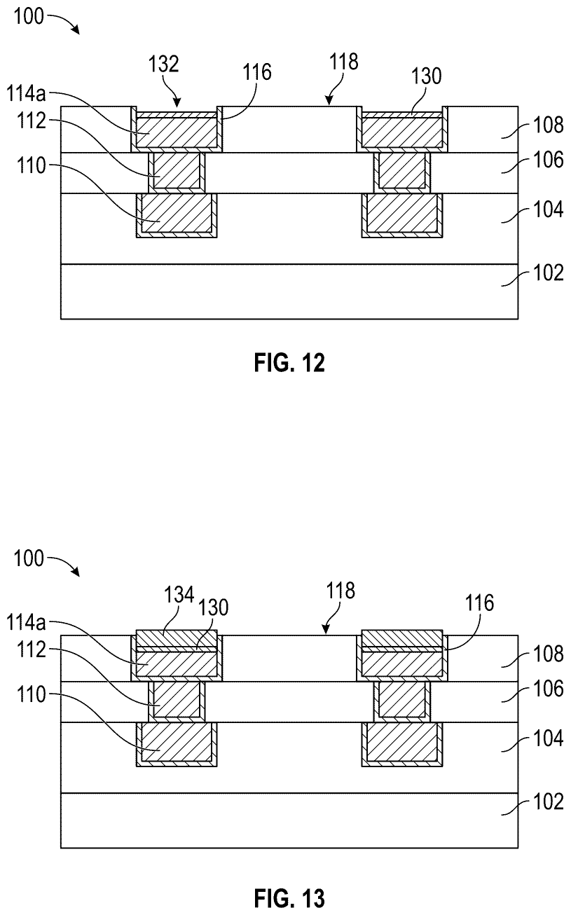

In FIG. 12, the excess metal material of the metal layer 130 over the barrier layer 116 and the portions of the barrier layer 116 disposed over the top of the second dielectric layer 108, and maybe a top portion of the dielectric layer 108, can be removed to leave a planarized upper surface 118, such as by CMP. The planarization can leave the upper surface 118 suitable for direct bonding for hybrid bonding embodiments. After the planarization process, the remaining metal layers 130 are confined on top of corresponding conductive features 114a, which are separated by the second dielectric layer 108. The metal layers 130 over the conductive features 114a may be recessed during the polishing or afterward to leave recesses 132, as shown in FIG. 12. The depth of the recesses 132 may be in a range of 5 nm-100 nm (e.g., 10 nm-80 nm, 20 nm-60 nm).

Moving to FIG. 13, the element 100 is exposed to an oxidation environment that oxidizes the metal layers 130 over the conductive features 114a, converting at least upper portions of the metal layers 130 to metal oxide layers 134. As such, each of the metal oxide layers 134 may be connected to a respective conductive feature 114a having a metal layer 130 sandwiched therebetween. Because such an oxidation process relies on diffusion, there may not exist a clear boundary between the metal oxide layer 134 and any remaining metal layer 130. In some embodiments, the oxidation process may consume all the metal layer 130. In this case, no metal layer 130 exists between the metal oxide layer 134 and the conductive feature 114a. The oxidation process may be a plasma oxidization (e.g., by exposure to an oxygen-containing plasma), thermal oxidization, ozone exposure, or wet oxidation (e.g., by exposure to inorganic or organic peroxides). In an example, the element 100 of FIG. 13 may be subjected to an ashing process, in which products of oxygen-containing plasma are supplied to the element. Since the metal oxide layer 134 is transformed by oxidizing the metal layer 130, which has a microstructure of ultra-fine grains, the metal oxide layer 134 may inherit ultra-fine grain microstructure, such as nanograins. Alternatively, a microstructure may be imparted by the oxidation process. For example, the metal oxide layer 134 may comprise grains having an average size (e.g., average of a maximum grain dimension) in the range of about 2 nm to 100 nm (e.g., an average size in the range of about 8 nm to 80 nm, or in the range of about 5 nm to 50 nm). Both the oxidation process and the resultant metal oxide layer 134 can be as described with respect to FIG. 4.

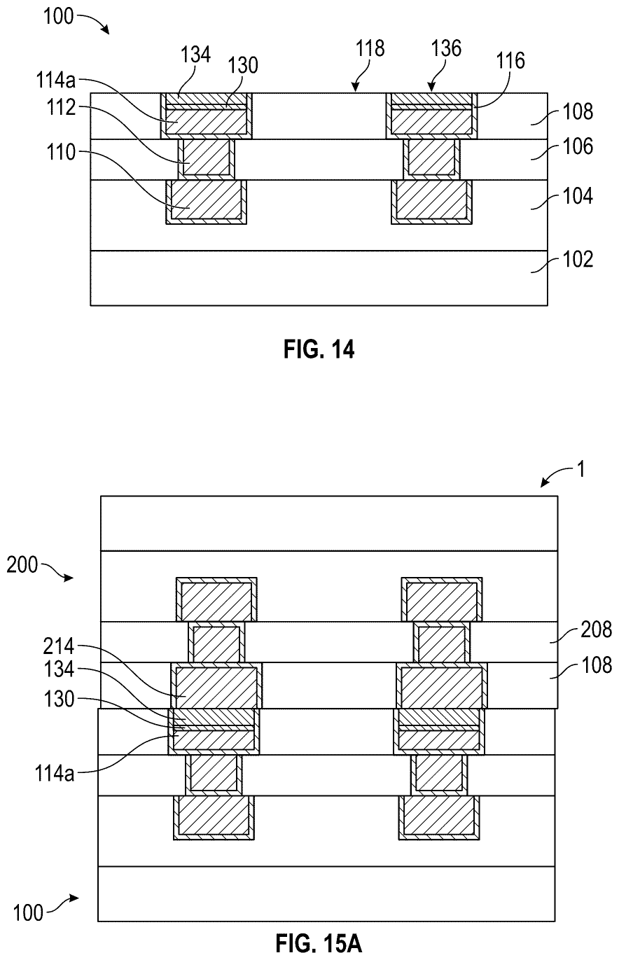

As also described with respect to FIG. 4, the oxidation process may cause the resultant metal oxide layer 134 to expand volume and protrude above the upper dielectric surface 118 of the hybrid bonding layer, as illustrated in FIG. 13. Therefore, in FIG. 14 a process (e.g., a planarization process or a wet or dry selective etch) may be applied to recess the metal oxide layers 134 to within the cavities in the second dielectric layer 108 where the metal oxide layer 124 protruded out. After the planarization process, e.g., the CMP process, the metal oxide layers 134 may be slightly recessed. In other embodiments, the metal oxide layers 134 may remain protruding. The upper surface 118 can be subjected to an activation and/or termination process, such as nitrogen treatment, to facilitate dielectric direct bonding, as described above.

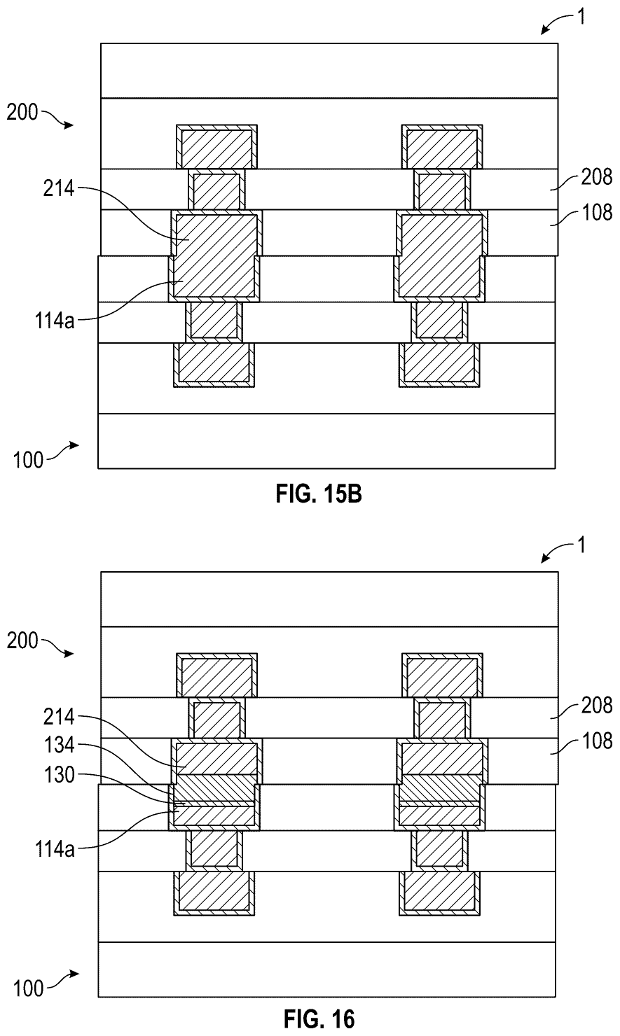

Referring to FIG. 15A, the element 100 (first element) is directly bonded to a second element 200 without an intervening adhesive, forming a bonded structure 1, by a bonding method described with respect to FIGS. 5-8. The second dielectric layer 108 of the first element 100 may be directly bonded to the dielectric layer 208 of the second element 200 at room temperature.

With reference to FIG. 15B, subsequently, the bonded structure 1 may go through an annealing process at an annealing temperature for a duration sufficient to complete bonding of the conductive features 114a to the conductive features 214. Bonds between the dielectric layers 108, 208 can also strengthen during the annealing. The elevated temperature of the annealing process and the extended duration may cause the metal material in the conductive features 114a, 214 (including metal in the underlying conductive features) to expand more than the surrounding dielectric materials 108, 208 due to the CTE mismatched discussed above with respect to FIG. 7A. This expansion may cause the metal oxide layer 134 to be pressed against the conductive layer 214.

Further, as described with respect to FIG. 7A, oxygen in the metal oxide layer 134 can be released and may diffuse into conductive features 114a and 214. Residual metal oxide may also diffuse into conductive features 114a and 214. Depending on annealing temperature and duration, at the end of the annealing process each of the conductive features 114a, including the metal layer 130 and the metal oxide layer 134, may merge to appear as one identifiable feature, as shown in FIG. 15B. As described above, the region close to the bonding interface may have higher oxygen content and higher residual metal oxide content. In some embodiments, residual portions of the metal layer 130 may be identifiable after annealing if the deposited metal layer 130 and the conductive feature 114a do not include the same metal. For example, in the process described with respect to FIG. 11, the metal layer 130 including copper may be deposited on the conductive feature 114a that has a different material.

As discussed with regard to FIG. 7A, the microstructure of ultra-fine grains (e.g., nanograins) of the metal oxide layer 134 can help achieve lower annealing temperature with good quality hybrid bonding of conductive features, when compared with bonding two semiconductor elements without the micro-structured metal oxide layer 134.

Referring to FIG. 16, in another embodiment the first element 100 of FIG. 13, including the metal oxide layers 134 protruding out of their cavities, can be used in hybrid bonding without recessing the metal oxide layers 134. To accommodate the protruding metal oxide layers 134 of the first element 100, the second element 200 may have recesses selectively formed at the conductive features 214. As such in the bonded structure 1 of FIG. 16, the bonding interfaces between the conductive features 114a and 214 are located in the cavities housing the conductive features 214 on the second element 200 side, as shown in FIG. 16. Subsequent anneal to complete bonding of the conductive features 114a, 214 may leave a hybrid bonded structure as described above with respect to FIG. 15B, except that the bonding interface between the conductive features 114a, 214, and consequent regions of higher oxygen concentrations, may be shifted toward the side of the element 200.

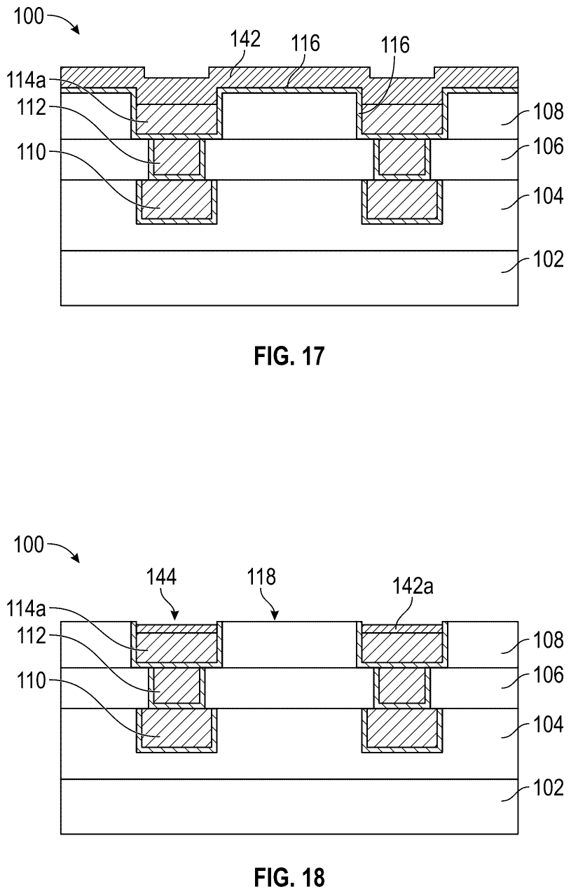

Another example embodiment process for forming a metal oxide layer over a conductive feature in a microelectronic structure is illustrated in FIGS. 17-18. The process starts at the status of the element 100 including recessed conductive features 114a as illustrated in FIG. 10. As shown in FIG. 17, the element 100 may be cleaned (e.g., by sputter-cleaning), and a metal oxide layer 142 may be directly coated over the element 100, including filling the recesses 128 and coating over the barrier layer 116. The metal oxide material 142 may comprise copper oxide deposited, for example, by high pressure reactive sputter coating. The reactive sputtering process may be performed in an argon (AR) ambient at 0.05 torr to 0.4 torr pressure to promote collisions between sputtered Cu atoms and the oxygen to form a copper oxide layer, which may include ultra fine grains (e.g., nanograins). As such the metal oxide material 142 may comprise an ultra-fine grain microstructure. The average size (e.g., average of a maximum grain dimension) of the metal oxide grains may be in the range of about 2 nm to 100 nm (e.g., an average size in a range of about 8 nm to 80 nm, or in a range of about 5 nm to 50 nm).

In FIG. 18, the excess metal oxide material layer 142 over the barrier layer 116 and the barrier layer 116 disposed over the upper surface of the second dielectric layer 108, and maybe a top portion of the dielectric layer 108, can be removed to leave a planarized upper surface 118, such as by CMP. The upper surface 118 can be sufficiently planarized for direct bonding. After the planarization process, the remaining metal oxide material 142 are the metal oxide layers 142a confined in cavities over their corresponding conductive features 114a, which are separated by the second dielectric layer 108. After the planarization process, the metal oxide layers 142a may be slightly recessed, or a subsequent recessing operation can be conducted. As noted above, due to the presence of the metal oxide layers 142a in the element 100 to be bonded, a smaller recess can be provided, which in turn promotes uniformity across the substrate and more reliable metal bonding.

The metal oxide material 142 can be directly deposited on the conductive features in other ways. For example, the metal oxide material 142 can be formed by spin-coating metal oxide grains onto the upper surfaces of the conductive features 114a. As another example, the metal oxide material layer 142 can be formed by electrolytic deposition methods or chemical vapor deposition (CVD) methods. The element 100 of FIG. 18 with metal oxide layers 142a can be activated and/or terminated, and directly bonded, particularly by hybrid bonding, to another element following the process described with respect to FIGS. 5-8.

Each of the methods set forth above may produce different microstructures of the metal oxide grains in the metal oxide layers 124, 134, 142a. For example, the oxidation process as illustrated in FIG. 4 causes metal oxide to grow from the existing upper surfaces of the conductive features 114a. As such, the microstructure of the metal oxide grains in the metal oxide layer 124 may carry unique signatures of the grain forming process. Further, different oxidation agents, for example, products of in situ or remote oxygen plasma, thermal oxidation, ozone exposure, wet chemical oxidation, or electrolytic oxidation, may cause different and unique signatures. If the metal oxide grains are converted from the coated metal layers 130 including a microstructure, as describe with respect to FIG. 13, the microstructure of the metal oxide layers 134 may carry unique signatures of the metal deposition and the in-situ oxidation process. If the metal oxide layer is directly deposited, whether by sputtering, spin-coating, or another method, on the conductive features 114a to form the metal oxide layers 142a, as shown in FIGS. 17-18, the microstructure of the metal oxide layer may show unique signatures of the specific direct deposition process. Other processes, e.g., electrolytic methods or CVD methods, may have their unique signatures in the microstructures of the formed oxide layers. Further, the post-anneal microstructure near the metal-metal interfaces of the bonded structure 1 may carry signatures indicative of the oxidation process for forming the metal oxide layers 124, 134, 142a.

Another potential benefit of the presently disclosed embodiments may be sidewall decoupling between the conductive features 114a and the surrounding second dielectric layer 108. Both oxidation embodiments and metal oxide deposition embodiments may, to different degrees, expose sidewalls of the conductive features 114a and/or adjacent barrier materials 116 to oxygen. Even slight oxidation of these sidewalls of the conductive features 114a can advantageously unpin or decouple the conductive features 114a from the surrounding insulating materials, as noted above with respect to FIG. 4. Such decoupling facilitates free expansion of the conductive features 114a relative to surrounding materials during the bonding anneal, permitting greater internal pressure for the metal bonding for a given recess size, or a smaller recess size for a given internal pressure. The sidewall decoupling signature may also benefit producing microelectronic elements with conductive features of different widths in a bonded structure by reducing variation in thermal expansion during the annealing for conductive features of different sizes, as will be discussed subsequently.

Further, in each of the methods described above, the microstructure (e.g., grain sizes) of the metal oxide layers may be controlled through process control parameters. For example, the size or diameter of the metal oxide grains may be fine-tuned through routine experimentation of oxidation or deposition conditions.

To the extent that both elements 100, 200 described above are individual device dies, the hybrid bonding processes illustrated in FIGS. 5-8 and FIGS. 15-16 can represent die-to-die (D2D) hybrid bonding involving a metal oxide layer at the bonding interface. The metal oxide layer can also be applied to wafer-to-wafter (W2W) hybrid bonding and die-to-wafer (D2W) hybrid bonding to reduce annealing temperature.

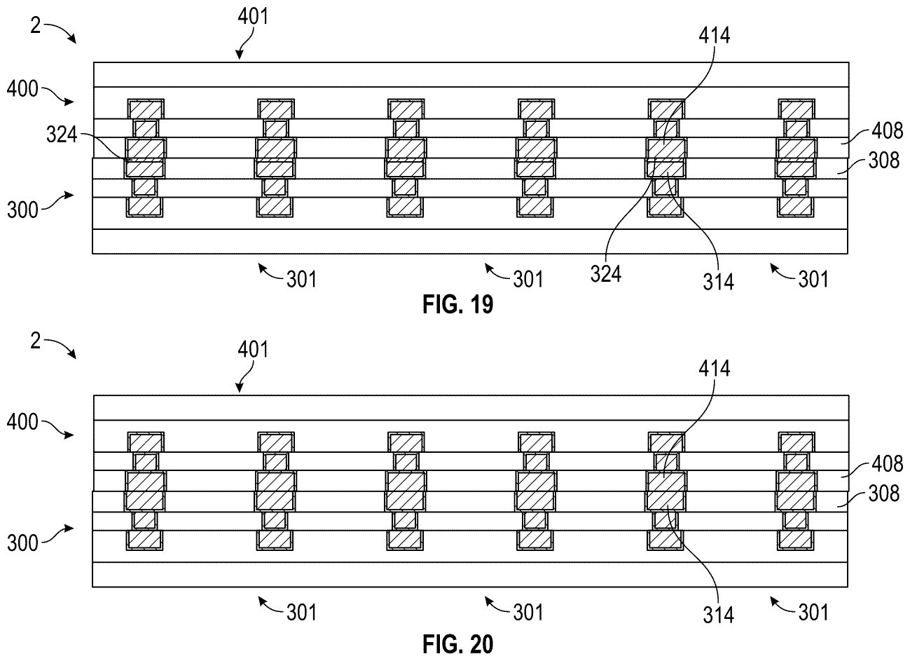

FIGS. 19-21 illustrate a hybrid bonding process to bond two wafer elements 300 and 400 together to form a W2 W bonded structure 2. In FIG. 19, the element 300 is a wafer that includes a plurality of die modules 301 that may be identical to each other. The plurality of die modules 301 may also not be identical to each other but may be arranged in the first wafer element 300 for subsequent singulation. Each of the die modules 301 includes one or more contact pads 314 (or other conductive features configured for contacting other conductive features) embedded in a dielectric layer 308. A metal oxide layer 324 is disposed on each contact pad 314 at the bonding surface of the first wafer element 300. As described above, the metal oxide layer 324 may comprise ultra-fine metal oxide grains, e.g., nanograins. FIG. 19 also shows the second wafer element 400 that includes a plurality of die modules 401, with each of the die modules 401 aligned with a corresponding die module 301 of the first wafer element 300. Each of the die modules 401 includes one or more contact pads 414 that are embedded in a dielectric layer 408. Both of the wafer elements 300, 400 are sufficiently planarized for direct bonding. One or both of the wafer elements 300, 400 may be activated and/or terminated for direct bonding, and the wafer elements 300, 400 are subsequently hybrid bonded together. In the illustrated embodiment, only the first wafer element 300 is provided with the metal oxide layer 324 on its contact pads 314; in other embodiments, such a metal oxide layer can be provided on the contact pads of both wafers.

Referring to FIG. 20, the bonded structure 2 including the wafer elements 300, 400 may go through an annealing process at an elevated temperature for a predetermined duration. As explained with respect to FIG. 7A, during the annealing process, due to the CTE mismatch between the metallic material of the contact pads 314, 414 and the surrounding dielectric material 308, 408, each contact pad 314, 414 can expand. As such, the contact pads 314, 314 are fused with the metal oxide layer 324 sandwiched therebetween. The microstructure of the metal oxide layer 324, comprising ultra-fine grains, can substantially lower the annealing temperature and facilitate interdiffusion and grain necking between the contact pads 314, 414, as described above. The fusion between the metal oxide layer 324 on the contact pads 314 and the contact pads 414 may result in a continuous bonded region 230, as shown in FIG. 7B. During the annealing process, metal oxide or free oxygen from the metal oxide layers 324 can diffuse though the surrounding materials, such that the resultant bonded contact pads 314, 414 can have a relatively high oxygen content as described above. The metal oxide layers 324 can facilitate lower anneal temperatures and freer thermal expansion compared to the absence of the metal oxide layers 324. As such, good quality bonding and electrical connection between the contact pads 314 of the first wafer element 300 and the contact pads 414 of the second wafer element 400 may be established at low bonding temperature. Residual microstructure signatures of the metal oxide layers 324 may or may not remain in the bonded structure 2 after annealing, depending upon the annealing conditions and the method the metal oxide layers 324 are formed.

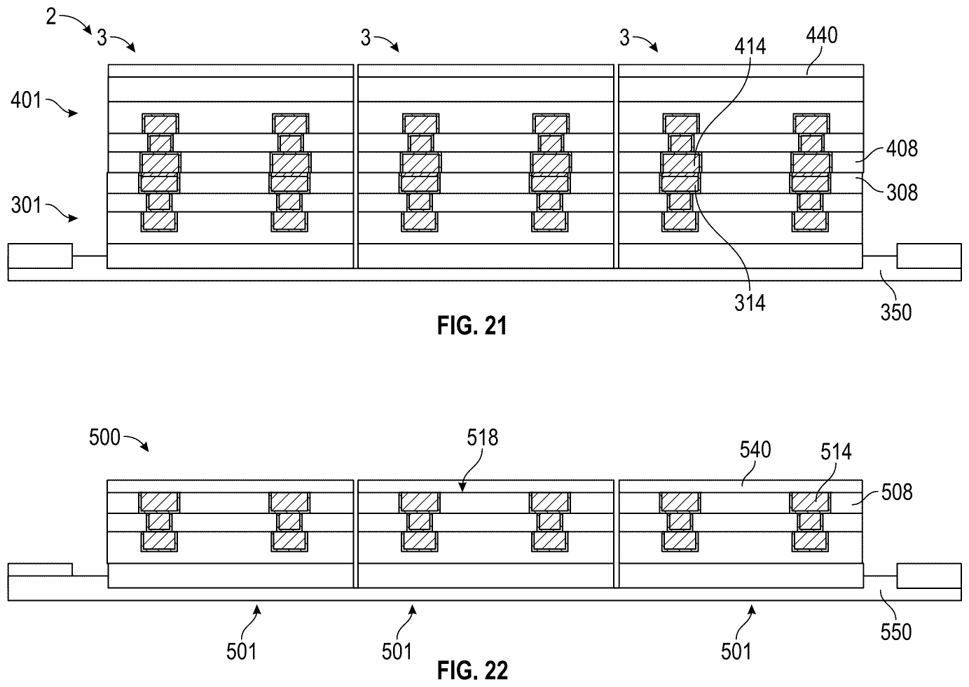

As shown in FIG. 21, the top surface of the W2 W bonded structure 2 may be coated with a protective layer 440. Subsequently, the bonded structure 2 may be singulated (e.g., by laser, saw, or plasma dicing) to separate the plurality of bonded modules 3. Sidewalls of individual modules 301, 401 of each bonded modules 3 can be flush with one another, as they are formed by a common singulation process. In FIG. 21, during the singulation process the bonded structure 2 may be supported by a dicing sheet 350.

FIGS. 22-26 illustrate a hybrid bonding process to bond dies to a wafer for D2 W bonding. Referring to FIG. 22, a wafer element 500 comprises a plurality of die modules that may be identical to each other or not identical to each other but can be arranged for subsequent bonded structure level singulation. Each of the die modules may include one or more contact pads 514 (or other conductive features) that are embedded in a dielectric layer 508 and may be recessed relative to the dielectric layer 508 as disclosed herein. As shown in FIG. 22, the wafer element 500 is supported by a dicing sheet 550 and is coated with a protective layer 540. Subsequently, the wafer element 500 is singulated (e.g., by mechanical dicing, laser dicing, or plasma dicing) to separate the die modules and form a plurality of dies 501. At this point, the dies 501 are supported by the dicing sheet 550, keeping the original lateral positions relative to each other. In some embodiments, the upper surface 518 of the wafer element 500 may be activated before coating of the protective layer 540. In some embodiments, the upper surface 518 of the wafer element 500 may be not activated before the coating process.

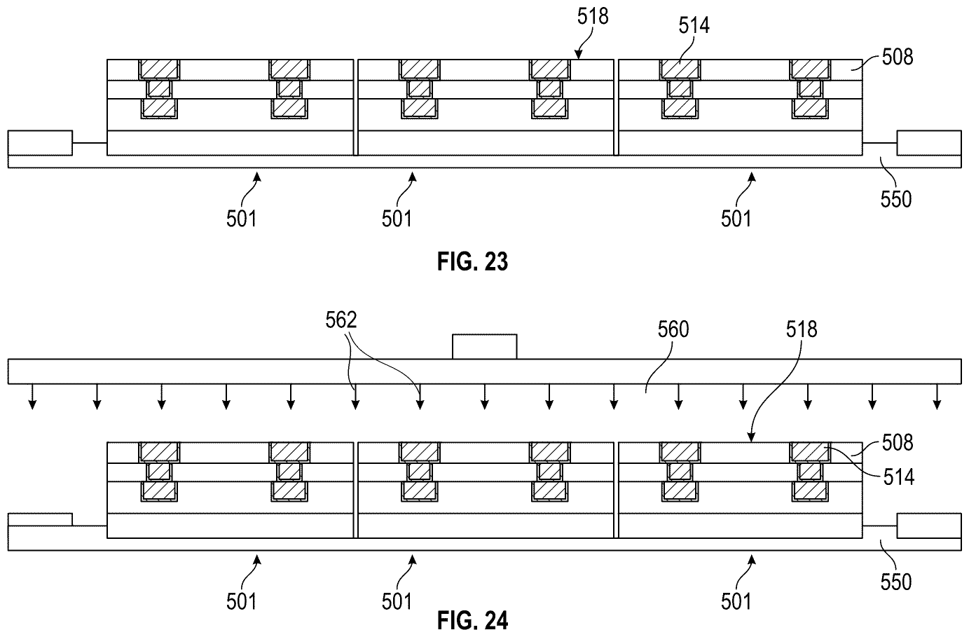

In FIG. 23, the protective layer 540 is stripped, exposing the upper bonding surface 518 of each singulated die 501. The dies 501 disposed on the dicing sheet 550 may be cleaned in preparation for subsequent processes. Note that the individual die modules may have been tested using probe pads of the wafer element 500 prior to singulation, or may be tested after singulation and removal of the protective layer 540, such that only known good dies (KGD) are employed in the subsequent bonding.

In FIG. 24, the plurality of dies 501 mounted on the dicing sheet 550 may go through an activation process to activate the upper surface 518 of each die 501 if the upper surface 518 is not already activated. The activation process may include exposing the plurality of dies 501 to products of a plasma 562 (e.g., remote or in situ oxygen-containing and/or nitrogen-containing plasma) in a treatment chamber 560 for a period of time. Subsequently the dies 501 may be rinsed and dried.

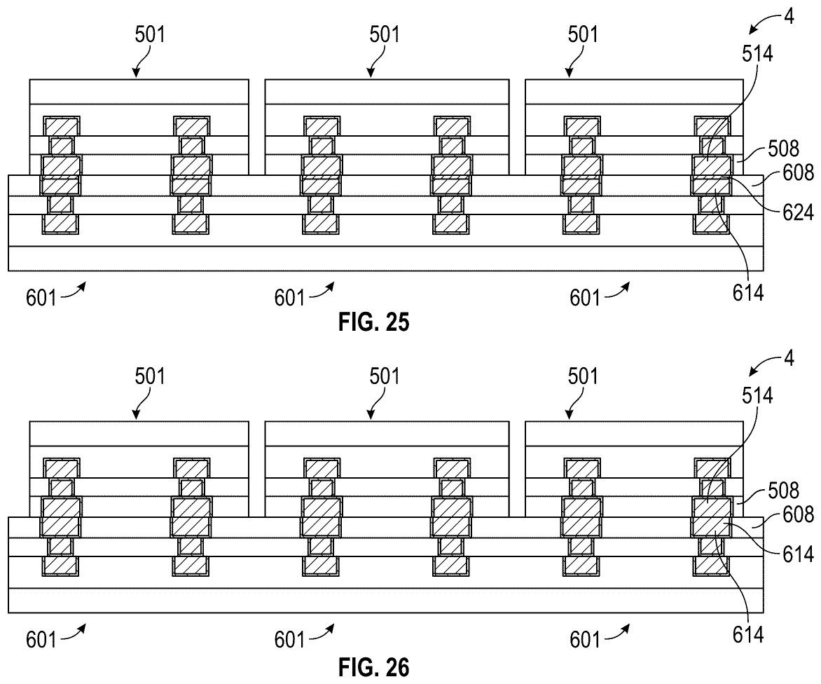

In FIG. 25, the plurality of dies 501 may be individually picked and placed onto corresponding die modules 601 of a wafer element 600, forming a bond and a D2 W bonded structure 4. Alternatively, the dies 501 may be mounted to a carrier and “gang” placed on the wafer element 600 with individual dies 501 aligned with individual die module 601. At this point the dielectric layer 508 of each dies 501 is bonded to a dielectric layer 608 of a corresponding die module 601 in the wafer element 600, which can be prepared for bonding, such as by sufficient planarization as described herein. In some embodiments, the bonding surface of the dielectric layer 508 is activated; in other embodiments both the dies 501 and the die modules 601 are activated. Each die module 601 of the element 600 includes one or more contact pads 614 that are embedded in the dielectric layer 608. As described with respect to the first wafer element 300 of FIG. 19, a micro-structured metal oxide layer 624 is disposed on each contact pad 614 at the bonding surface of the die modules 601 (e.g., selectively formed by oxidation for hybrid bonding). The metal oxide layer 624 may comprise ultra-fine metal oxide grains (e.g., nanograins). The initial bonding of the dies 501 to the wafer element 600 can be conducted at room temperature, and aligned contact pads 514, 614 with the intervening metal oxide layer 624 disposed therebetween can have gaps therebetween at this stage. The gaps, if present, can be relatively small in view of metal oxide layers 624 facilitating uniform and reliable metal bonding across the wafer 600 at relatively low temperatures, compared to processes without the metal oxide 624.

Referring to FIG. 26, the D2 W bonded structure 4 including the dies 501 and the wafer element 600 is subjected to an annealing process at an elevated temperature. As described with respect to FIG. 7A, FIG. 15 and FIG. 20, during the annealing process, due to the CTE mismatch between the metallic material of the contact pads 514, 614 (and conductive features) and the surrounding dielectric material 508, 608 each contact pad 514, 614 can expand. Accordingly, the contact pad 614 is pressed against and fused with the corresponding contact pad 514 with the metal oxide layer 624 sandwiched therebetween. As described above, the metal oxide layer 624 can have an ultra-fine grain (e.g., nanograins) microstructure, which can substantially lower the anneal temperature for metal-to-metal bonding and encourages interdiffusion and resultant grain necking across the interface, as described above. The fusion between the metal oxide layer 624 on the contact pad 614 and the contact pad 514 may result in a continuous bonded region, as discussed with respect to FIG. 7B. As such, good quality bonding and electrical connection between the contact pads 614 of the wafer element 600 and the contact pads 514 of the dies 501 may be established. As discussed above, when at least one of the wafer element 600 and the wafer element 500 (e.g., the die modules 501) includes a metal oxide layer in each respective contact pad 514 or 614, the annealing temperature can be substantially reduced. During the annealing process, metal oxide or free oxygen from the metal oxide layers 624 can diffuse though the surrounding materials, such that the resultant bonded contact pads 514, 614 can have a relatively high oxygen content as described above (e.g., saturated or supersaturated with oxygen). The metal oxide layers 624 can facilitate lower anneal temperatures and freer thermal expansion compared to the absence of the metal oxide layers 624. Residual microstructure signatures of the metal oxide layer 624 may or may not remain in the bonded structure 4 after annealing, depending upon the annealing conditions and the method the metal oxide layers 624 were formed.

Subsequently, the bonded structure 4 may be singulated, e.g., by mechanical dicing, laser dicing, or plasma dicing, to separate into the plurality of bonded modules, each comprising a die 501 and die from the separated die modules 601 hybrid bonded together. Each singulated bonded module can be equivalent to a D2D bonded structure 1 of FIG. 7A, although difference may exist, particularly if gaps between the dies 501 are filled prior to singulation.

Although shown and discussed with the example of semiconductor dies and wafers, the skilled artisan will appreciate that metal oxide can be provided on contact pads in a hybrid bonding layer for other types of microelectronic elements. For example, such microelectronic elements may include an interposer, a semiconductor package, a flat panel, a dielectric substrate, surface mount devices, passive devices, MEMS devices, etc.

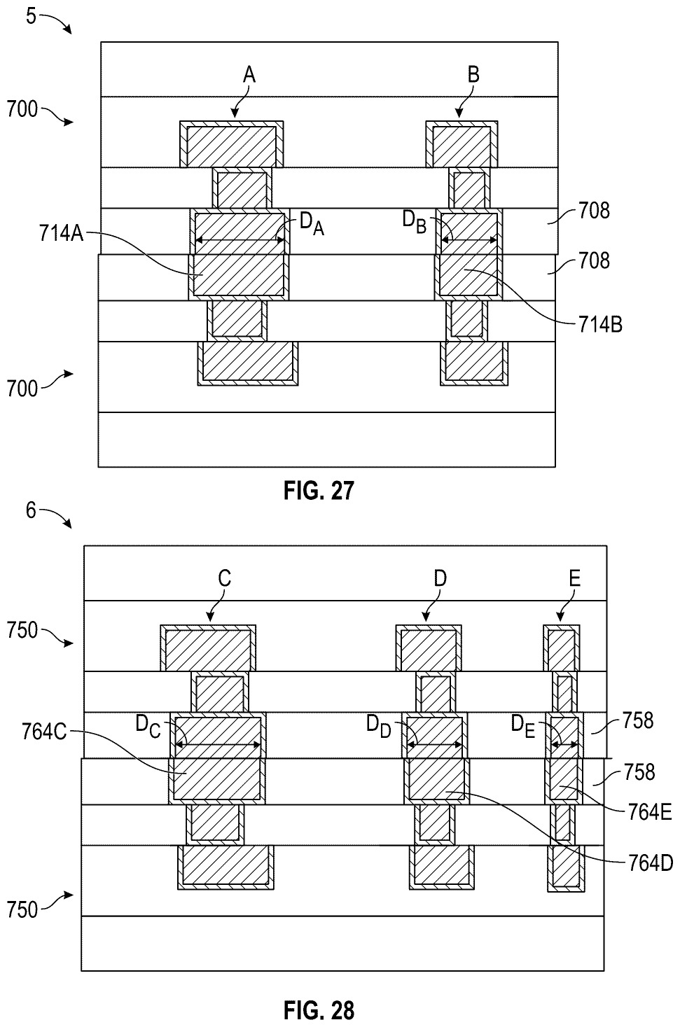

The characteristics of decoupling sidewalls (e.g., gap forming) between the conductive features and surrounding insulating material may benefit forming conductive features of different widths across the bonding interface in a bonded structure without sacrificing uniformity of metal bonding across the substrate. In FIG. 27, a bonded structure 5 comprises two elements 700, which comprises two columns of conductive features A and B. As can be seen in FIG. 27, the width D_{A} of first conductive features 714A is greater than the width D_{B} of second conductive features 714B on the right side, and similarly for corresponding conductive feature of the upper element 700. At least one of the elements 700 comprises metal oxide layers (not shown) over the conductive features 714A, 714B before hybrid bonding. With the metal oxide layers over the conductive features 714A, 714B having a microstructure as disclosed herein, and consequent decoupling of the conductive feature sidewalls from surrounding insulating material 708, the widths D_{A} and D_{B} of the conductive features can be made significantly different from each other without sacrificing uniformity in the metal bonding across the substrate. As illustrated in FIG. 27, D_{A}>D_{B}.

Referring to FIG. 28, a bonded structure 6 comprises three conductive features C, D, E having significantly different widths D_{C}, D_{D}, and D_{E} respectively. When each of the conductive features 764C, 764D, and 764E comprises a metal oxide layer (not shown) at the hybrid bonding interface, the widths D_{C}, D_{D}, and D_{E} can be significantly different from one another without sacrificing uniformity in the metal bonding across the substrate. As shown in FIG. 28, D_{C}>D_{D}>D_{E}.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

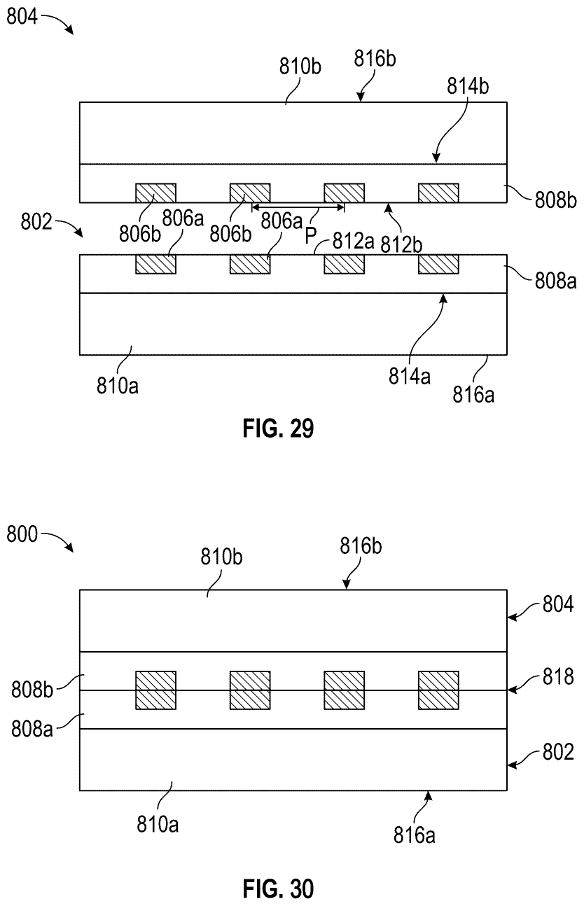

FIGS. 29 and 30 schematically illustrate cross-sectional side views of first and second elements 802, 804 prior to and after, respectively, a process for forming a directly bonded structure, and more particularly a hybrid bonded structure, according to some embodiments. In FIG. 30, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a. 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C. 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a. 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2 W), die-to-die (D2D), or die-to-wafer (D2 W) bonding processes. In W2 W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a. 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a. 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 29 prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

In one aspect of the disclosure, a process for hybrid bonding includes providing a first element and a second element, and bonding the first element to the second element. The first element includes a first dielectric material having a first bonding surface, a first conductive feature at least partially embedded in the first dielectric material, and a metal oxide layer formed over the first conductive feature and exposed at the first bonding surface. The second element includes a second dielectric material having a second bonding surface and a second conductive feature at least partially embedded in the second dielectric material. The process of bonding the first element to the second element includes directly bonding the first dielectric material to the second dielectric material with the metal oxide layer between the first conductive feature and the second conductive feature.

In some embodiments, direct bonding the first dielectric material to the second dielectric material is conducted at room temperature.

In some embodiments, the process for hybrid bonding further includes annealing the first element and the second element at an annealing temperature to directly bond the first conductive feature to the second conductive feature. In some embodiments, a metal of the metal oxide is copper and the annealing temperature is below about 250° C. In some embodiments, the first conductive feature includes one or more of copper, nickel, gold, indium, molybdenum, zinc, tungsten, tantalum, and titanium, and the second conductive feature includes one or more of copper, nickel, gold, indium, molybdenum, zinc, tungsten, tantalum, and titanium.

In another aspect of the disclosure, a microelectronic structure for low temperature hybrid bonding includes a first bonding layer having a first upper surface prepared for hybrid bonding. The first bonding layer includes a first conductive feature, where the first conductive feature has a metal oxide layer disposed thereover and the metal oxide layer is exposed at the first upper surface. A first dielectric material is surrounding the first conductive feature, where the first dielectric material is exposed at the first upper surface.

In some embodiments, the first conductive feature includes one or more of copper, nickel, gold, indium, molybdenum, zinc, tungsten, tantalum, and titanium.

In some embodiments, the first conductive feature is at least partially separated from the surrounding dielectric material, where the separation is at least partially by the provided metal oxide.

In some embodiments, the metal oxide layer includes copper oxide. The metal oxide layer has a thickness of at least about 20 nm. Further, the first upper surface formed by the metal oxide layer has a surface roughness of at least 2 nm RMS.

In some embodiments, the oxide layer includes nanograins. The nanograins have an average maximum dimension in the range of about 2 nm to 100 nm.

In some embodiments, the metal oxide layer is formed by oxidizing a metal of the first conductive feature. The oxidizing is plasma oxidizing, thermal oxidizing, ozone exposure, or wet oxidizing with an inorganic or organic peroxide.

In another aspect of the disclosure, a bonded structure includes a first element and a second element, where the first element is directly bonded to the second element. The first element includes a first bonding layer. The first bonding layer includes a first dielectric material having a first upper surface, and a first conductive feature at least partially embedded in the first dielectric material at the upper surface. The second element includes a second bonding layer. The second bonding layer includes a second dielectric material having a second upper surface, and a second conductive feature at least partially embedded in the second dielectric material at the second upper surface. Direct bonding of the first element and the second element includes direct bonding the first upper surface to the second upper surface at a bond interface, where the first conductive feature is directly bonded to the second conductive feature to form a bonded contact, and the bonded contact has an oxygen content greater than 100 ppm of oxygen in metal (e.g., copper) within about 100 nm of the bond interface.

In some embodiments, the second conductive feature include one or more of copper, nickel, gold, indium, molybdenum, zinc, tungsten, tantalum, and titanium.

In some embodiments, oxygen content is greater than an oxygen saturation level in the first and/or second conductive feature within 100 nm of the bond interface. In some embodiments, the oxygen content in the bonded contact includes oxygen in a metal oxide formed from a metal of the first conductive structure.

In yet another aspect of the disclosure, a process for preparing a first element for direct hybrid bonding to a second element includes providing a metal oxide layer forming an upper portion of a first conductive feature of the first element, and preparing a first bonding surface of a first bonding layer for direct hybrid bonding. The first conductive feature is embedded in a first dielectric material, where the first conductive feature and the first dielectric material form the first bonding layer of the first element, and the metal oxide layer of the first conductive feature is exposed at the first bonding surface.

In some embodiments, the metal oxide layer comprises an oxide of a metal of the first conductive feature. In some embodiments, the first conductive feature comprises a metal. Further, the metal of the first conductive feature and a metal in the metal oxide layer can be copper, nickel, gold, indium, molybdenum, zinc, tungsten, tantalum, or titanium.

In some embodiments, the metal oxide layer comprises nanograins. The nanograins have an average maximum dimension in the range of about 2 nm to 100 nm.

In some embodiments, the process for preparing a first element for direct hybrid bonding to a second element further comprises before providing the metal oxide layer over the first conductive feature, forming a recess into the first conductive feature relative to an upper surface of the first bonding layer. The recess is in the range of about 10 nm to 50 nm relative to the upper surface.

In some embodiments, providing the metal oxide layer over the first conductive feature includes depositing a layer of conductive material over the first conductive feature and oxidizing the layer of conductive material. In some embodiments, providing the metal oxide layer includes oxidizing a material of the first conductive feature. In some embodiments, oxidizing a material of the first conductive feature comprises exposing the first element to a product of an oxygen plasma. In some embodiments, oxidizing a material of the first conductive feature comprises thermal oxidation. In some embodiments, oxidizing a material of the first conductive feature comprises wet oxidation. In some embodiments, providing the metal oxide layer comprises sputtering the metal oxide layer onto the first conductive feature and the first dielectric material.

In some embodiments, preparing the first bonding surface comprises planarizing the first bonding surface. preparing the first bonding surface further includes activating a surface of the first dielectric material.

In yet another aspect of the disclosure, a microelectronic device includes a base substrate, a first hybrid bonding layer disposed on the base substrate where the first hybrid bonding layer having a bonding surface, a dielectric material forming part of the first hybrid bonding layer, and at least one first conductive feature embedded in a dielectric material. The at least first one conductive feature is exposed at the bonding surface, and the at least one first conductive feature has an oxide portion at the bonding surface.

In some embodiments, the oxide portion comprises nanograins.

In some embodiments, the base substrate comprises silicon, interposer, semiconductor package, flat panel, or dielectric substrate.

Unless the context clearly requires otherwise, throughout the description and the claims, the words “comprise.” “comprising.” “include.” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A process for hybrid bonding, comprising:
providing a first element comprising a first dielectric material having a first bonding surface, a first conductive feature at least partially embedded in the first dielectric material, a metal oxide layer formed over the first conductive feature and exposed at the first bonding surface;
providing a second element comprising a second dielectric material having a second bonding surface, a second conductive feature at least partially embedded in the second dielectric material; and
direct bonding the first element to the second element, including directly bonding the first dielectric material to the second dielectric material with the metal oxide layer between the first conductive feature and the second conductive feature.

2. The process of claim 1, wherein direct bonding the first dielectric material to the second dielectric material is conducted at room temperature.

3. The process of claim 1, further comprising annealing the first element and the second element at an annealing temperature to directly bond the first conductive feature to the second conductive feature.

4. The process of claim 3, wherein a metal of the metal oxide is copper and the annealing temperature is below about 250° C.

5.-6. (canceled)

7. The process of claim 4, wherein the first conductive feature comprises one or more of copper, nickel, gold, indium, molybdenum, zinc, tungsten, tantalum, and titanium.

8. The process of claim 4, wherein the second conductive feature comprises one or more of copper, nickel, gold, indium, molybdenum, zinc, tungsten, tantalum, and titanium.

9. A microelectronic structure for low temperature hybrid bonding, comprising:
a first bonding layer having a first upper surface prepared for hybrid bonding, the first bonding layer comprising:
a first conductive feature, the first conductive feature having a metal oxide layer disposed thereover, the metal oxide layer exposed at the first upper surface, and
a first dielectric material surrounding the first conductive feature, the first dielectric material exposed at the first upper surface.

10. The microelectronic structure of claim 9, wherein the first conductive feature comprises one or more of copper, nickel, gold, indium, molybdenum, zinc, tungsten, tantalum, and titanium.

11. The microelectronic structure of claim 10, wherein the first conductive feature is at least partially separated from the surrounding dielectric material, wherein the separation is at least partially by the disposed metal oxide.

12. The microelectronic structure of claim 9, wherein the metal oxide layer comprises copper oxide.

13. The microelectronic structure of claim 12, wherein the metal oxide layer has a thickness of at least about 20 nm.

14. The microelectronic structure of claim 9, wherein the first upper surface formed by the metal oxide layer has a surface roughness of at least 2 nm RMS.

15. The microelectronic structure of claim 9, wherein the oxide layer comprises nanograins.

16. The microelectronic structure of claim 15, wherein the nanograins have an average maximum dimension in the range of about 2 nm to 100 nm.

17. The microelectronic structure of claim 9, wherein the metal oxide layer is formed by oxidizing a metal of the first conductive feature.

18. The microelectronic structure of claim 17, wherein the oxidizing is plasma oxidizing, thermal oxidizing, ozone exposure, or wet oxidizing with an inorganic or organic peroxide.

19. A bonded structure, comprising:
a first element, the first element comprising a first bonding layer, the first bonding layer comprising:
a first dielectric material having a first upper surface, and
a first conductive feature at least partially embedded in the first dielectric material at the upper surface;
a second element, the second element comprising a second bonding layer, the second bonding layer comprising:
a second dielectric material having a second upper surface, and
a second conductive feature at least partially embedded in the second dielectric material at the second upper surface; and
wherein the first upper surface is directly bonded to the second upper surface at a bond interface, and the first conductive feature is directly bonded to the second conductive feature to form a bonded contact, the bonded contact having an oxygen content greater than 100 ppm of oxygen in metal within about 100 nm of the bond interface.

20. The bonded structure of claim 19, wherein the second conductive feature comprises one or more of copper, nickel, gold, indium, molybdenum, zinc, tungsten, tantalum, and titanium.

21. The bonded structure of claim 19, wherein oxygen content is greater than an oxygen saturation level of the first and/or second conductive features within 100 nm of the bond interface.

22. The bonded structure of claim 19, wherein the oxygen content in the bonded contact includes oxygen in a metal oxide formed from a metal of the first conductive structure.

23.-41. (canceled)
